(19) United States
(12) Patent Application Publication
(10) Pub. No.: US 2022/0093309 A1
(43) Pub. Date: Mar. 24, 2022

(54) INTEGRATED INDUCTOR STRUCTURE AND INTEGRATED CIRCUIT

(71) Applicant: ANHUI ANUKI TECHNOLOGIES CO., LTD., Hefei, Anhui (CN)

(72) Inventors: Sheng WEI, Hefei, Anhui (CN); Wei CHENG, Hefei, Anhui (CN); Xiaodong WANG, Hefei, Anhui (CN); Chengjie ZUO, Hefei, Anhui (CN); Jun HE, Hefei, Anhui (CN)

(21) Appl. No.: 17/426,246

(22) PCT Filed: May 24, 2019
(86) PCT No.: PCT/CN2019/088229

§ 371 Date: Jul. 28, 2021

(30) Foreign Application Priority Data
Jan. 29, 2019 (CN) 201910085845.8
Jan. 29, 2019 (CN) 201920153379.8

(51) Int. Cl. H01F 27/00; H01F 27/29

(52) U.S. Cl. CPC H01F 27/006; H01F 27/292

(57) ABSTRACT

Provided are an integrated inductor structure and an integrated circuit. The integrated inductor structure includes: at least two plane inductors, which are sequentially stacked, and different plane inductors are formed in metal layers with different functional modules; and at least one connection part, which is arranged between two adjacent functional modules, and each two adjacent plane inductors are electrically connected through the connection part.

This application claims priority to Chinese patent applications No. 201910085845.8 and No. 201920153379.8 filed with the CNIPA on Jan. 29, 2019, disclosure of which are incorporated herein by reference in their entireties.

### TECHNICAL FIELD

The present disclosure relates to integrated circuit technologies, for example, an integrated inductor structure and an integrated circuit.

### BACKGROUND

With the increasing development of electronic products, the research and development of various components are moving towards high integration and multiple functions. Therefore, the requirements for the integrated circuit are increasing.

In the integrated circuit design, the design for the inductor is often a difficult problem. At the present stage, the inductor in the integrated circuit usually has two problems. One is that the quality factor (i.e., the Q value) of the inductor is low, which influences the circuit performance. The other is that the inductor area is large, which influences the circuit integration, size and manufacture cost. However, how to increase the Q value of the inductor on the premise of keeping the inductor area unchanged has always been a big problem in industry.

### SUMMARY

In view of this, the present disclosure proposes an integrated inductor structure and an integrated circuit to increase the Q value of the inductor while ensuring the circuit integration level.

The present disclosure uses the solutions described below.

In a first aspect, an embodiment of the present disclosure provides an integrated inductor structure, including:

at least two plane inductors, which are sequentially stacked, and different plane inductors are formed in metal layers with different functional modules; and

at least one connection part, which is arranged between two adjacent functional modules, and each two adjacent plane inductors are electrically connected through the connection part.

In an embodiment, a connection mode of the at least two plane inductors is at least one of: a series connection and a parallel connection.

In an embodiment, each two adjacent plane inductors have an overlapping part in a direction perpendicular to a plane in which the plane inductors are located.

In an embodiment, the overlapping part of each two adjacent plane inductors has a same current direction.

In an embodiment, the plane inductor is a plane spiral structure.

In an embodiment, the connection part comprises at least one of: a solder ball and a metal pillar.

In an embodiment, the at least two plane inductors include a first plane inductor and a second plane inductor, and the functional module includes a chip and a package substrate; and

the first plane inductor is formed in a metal layer of the chip and the second plane inductor is formed in a metal layer of the package substrate.

In an embodiment, the chip is a flip chip.

In an embodiment, the connection part is at least one of: a tin ball and a copper pillar for bonding the flip chip.

In another aspect, an embodiment of the present disclosure provides an integrated circuit, including an integrated inductor structure provided by any embodiment of the present disclosure.

The integrated inductor structure provided by the present disclosure includes: at least two plane inductors, which are sequentially stacked, and different plane inductors are formed in metal layers with different functional modules; and at least one connection part, which is arranged between two adjacent functional modules, and each two adjacent plane inductors are electrically connected through the connection part. In the technical solutions of the present disclosure, at least two plane inductors are sequentially stacked and different plane inductors are formed in metal layers with different functional modules, so that a distance between two adjacent plane inductors is larger than the thickness of the plane inductor. On one hand, the Q value of the inductor can be effectively increased on the premise of keeping the inductor area unchanged, i.e. the Q value of the inductor is increased on the premise of ensuring the circuit integration level, or the inductor area is reduced on the premise of keeping the Q value of the inductor, thus reducing the area of the integrated circuit. On the other hand, the interference between multiple plane inductors can be reduced, and the parasitic capacitance between different plane inductors can be greatly reduced in a case where the mutual inductance between different plane inductors is not greatly reduced. In addition, at least two plane inductors are sequentially stacked, so that the inductance value of the inductor in the integrated inductor structure can be increased.

### BRIEF DESCRIPTION OF DRAWINGS

FIG. 1 is a schematic sectional view of an integrated inductor structure according to an embodiment of the present disclosure;

FIG. 2 is a perspective view of an integrated inductor structure according to an embodiment of the present disclosure;

FIG. 3 is a plan view of an integrated inductor structure according to an embodiment of the present disclosure;

FIG. 4 is a schematic sectional view of another integrated inductor structure according to an embodiment of the present disclosure; and

FIG. 5 is a plan view of an inductor in an integrated inductor structure in the related art.

### DETAILED DESCRIPTION

Solutions of the present disclosure are further described below through implementations in conjunction with the drawings. It is to be understood that the embodiments set forth below are intended to illustrate, but not to limit, the present disclosure. It is to be noted that to facilitate description, only part, not all, of structures related to the present disclosure are illustrated in the drawings.

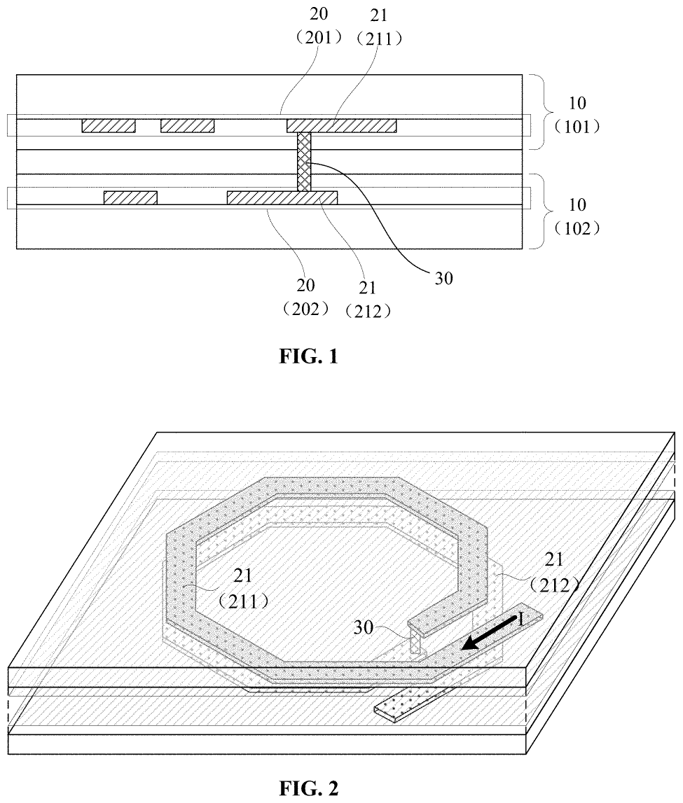

FIG. 1 is a schematic sectional view of an integrated inductor structure according to an embodiment of the present disclosure. The integrated inductor structure provided by the embodiment of the present disclosure is suitable for an integrated circuit which requires the inductor to have a high Q value. As shown in FIG. 1, the integrated inductor structure provided by this embodiment includes at least two planar inductors 21 and at least one connection part 30.

The at least two plane inductors 21 are sequentially stacked, and different plane inductors 21 are formed in metal layers 20 in different functional modules 10.

The at least one connection part 30 is disposed between adjacent functional modules 10, and each two adjacent plane inductors 21 are electrically connected through one connection part 30.

In this embodiment, each functional module 10 may be a chip or a substrate (e.g., a package substrate). Exemplarily, different functional modules 10 may be different chips, different substrates, or different combinations of the chip and the substrate. Different plane inductors 21 are formed in the existing metal layers 20 (the metal layers forming circuit patterns) of different functional modules 10. In this case, the existing metal layers 20 of the functional modules 10 may be used for patterning the plane inductors 21 to reduce the processes and the thickness of the integrated inductor structure.

In an integrated circuit, there is a high requirement for the inductor configuration. In some applications, the inductor in the integrated circuit is required to have a high inductance value and a high Q value, and the area of the integrated circuit is required to be reduced, so that high integration can be implemented.

In general, to obtain the inductance with a higher Q value, it is necessary to increase the thickness of the inductor coil. However, increasing the thickness of the inductor coil may cause the inductance value of the inductor per unit area to decrease, and increasing the inductor area to increase the inductance value may cause the Q value of the inductor to decrease, thus the circuit performance is affected. In this case, the designer needs to make a trade-off between the inductance value and the Q value per unit area. Therefore, how to achieve an increase in the inductance value and/or the Q value in the same area becomes a difficult problem.

Based on the above technical problem, the inventors have found that through stacking at least two plane inductors and electrically connecting the at least two plane inductors through at least one connection part to integrally form an inductor stacking structure, the inductance value can be increased while keeping the inductor area unchanged. At the same time, when the distance between two adjacent plane inductors is disposed to be greater than the thickness of the plane inductor, the Q value of the inductor can be increased. However, through further studying, the inventors have found that when the above inductor stacking structure is formed on a same substrate, it is necessary to separately form a connection layer for preparing the connection part, resulting in that the thickness of the integrated circuit is increased and the process difficulty is increased. Additionally, the thickness of the connection layer is relatively small so that the increase of the Q value of the inductor is not obvious.

Based on this, the embodiment of the present disclosure configures different plane inductors in different functional modules, and implements the electrical connection of the multiple plane inductors through the connection parts between the functional modules to form the integrated inductor structure. Since the thickness of the functional module itself is large, the distance between two adjacent plane inductors may be configured to be large, thereby effectively increasing the Q value of the inductor. In addition, the connection part may be formed by using the connection layer between the functional modules, thus avoiding separately preparing of the connection part, reducing the process difficulty, and reducing the thickness of the integrated circuit.

It should be noted that FIG. 1 only exemplarily illustrates that the integrated inductor structure includes two plane inductors. As shown in FIG. 1, the integrated inductor structure includes a first plane inductor 211, a second plane inductor 212 and a connection part 30, where the first plane inductor 211 and the second plane inductor 212 are stacked, the first plane inductor 211 is disposed in a first metal layer 201 of a first functional module 101, the second plane inductor 212 is disposed in a second metal layer 202 of a second functional module 102, and the first plane inductor 211 is electrically connected to the second plane inductor 212 through the connection part 30.

In addition, multiple plane inductors may be correspondingly formed in each functional module to form multiple inductances. The present disclosure does not limit the number of the inductors, plane distribution of the inductors, area occupied by the inductors, functional modules in which the plane inductors are located and the like, which are specifically determined according to practical situations.

In the integrated inductor structure provided by the embodiments of the present disclosure, at least two plane inductors are sequentially stacked and different plane inductors are formed in metal layers with different functional modules, so that a distance between two adjacent plane inductors is larger than the thickness of the plane inductor. On one hand, the Q value of the inductor can be effectively increased on the premise of keeping the inductor area unchanged, that is, the Q value of the inductor is increased on the premise of ensuring the circuit integration level, or the inductor area is reduced on the premise of keeping the Q value of the inductor, thus reducing the area of the integrated circuit. On the other hand, the interference between multiple plane inductors can be reduced, and the parasitic capacitance between different plane inductors can be greatly reduced in a case where the mutual inductance between different plane inductors is not greatly reduced. In addition, at least two plane inductors are sequentially stacked so that the inductance value of the inductor in the integrated inductor structure can be increased.

To ensure the conductivity of the integrated inductor structure described above, the connection part 30 may be formed of a metal having a high conductivity. Optionally, the connection part 30 includes a solder ball and/or a metal pillar.

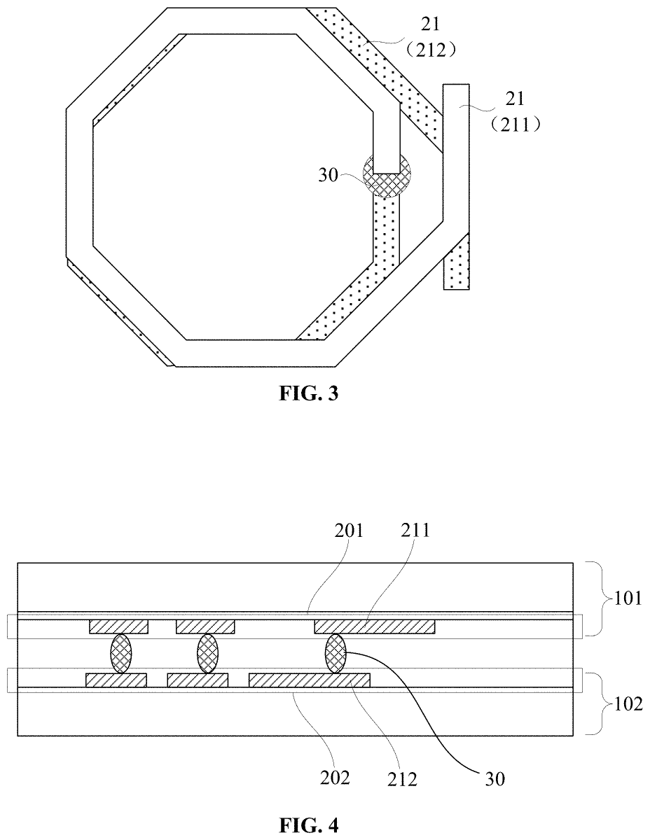

FIG. 2 is a perspective view of an integrated inductor structure according to an embodiment of the present disclosure. FIG. 3 is a plan view of an integrated inductor structure according to an embodiment of the present disclosure. As shown in FIGS. 2 and 3, the plane inductor 21 may have a plane spiral structure.

It is to be noted that the plane spiral inductor is easy to be integrated and has a low cost. Therefore, the plane inductor may be configured to have the plane spiral structure. However, the plane inductor configured to have the plane spiral structure is merely an example provided by this embodiment, and is not intended to limit the present disclosure. The plane inductor may have a structure of another shape.

In an embodiment, the at least two plane inductors may be connected in series and/or in parallel.

The plane inductors 21 in the different metal layers 20 may be connected through the connection part(s) 30 according to actual demands. The plane inductors 21 may be connected in series or in parallel, or partially connected in series and partially connected in parallel.

Exemplarily, referring to FIG. 2, when the multiple plane inductors 21 are connected in series, a total inductance value in the integrated inductor structure is a sum of the inductance values of the multiple plane inductors 21 described above. Therefore, in a case where the inductance value in the integrated inductor structure is required to be relatively large, the multiple plane inductors 21 may be configured to be connected in series.

In an embodiment, each two adjacent plane inductors may overlap in a direction perpendicular to a plane in which the plane inductors are located.

Exemplarily, referring to FIG. 3, in the direction perpendicular to the plane in which the plane inductors are located 21, two adjacent plane inductors (the first plane inductor 211 and the second plane inductor 212) overlaps, so that the area occupied by the inductor formed by the plane inductors can be reduced, thereby reducing the area of the integrated circuit.

In an embodiment, the overlapping part of each two adjacent plane inductors may have a same current direction.

When there is a certain distance between adjacent plane inductors 21, a mutual inductance may be generated between the plane inductors 21. When adjacent plane inductors 21 have the same current direction (the orientation of I in FIG. 2) and have an overlapping area in the direction perpendicular to the plane where the plane inductors are located, the adjacent plane inductors 21 have magnetic fields in the same direction, and a magnetic flux through the plane inductors 21 increases, thereby increasing the mutual inductance value between the plane inductors 21 and further increasing the total inductance value of the integrated inductor structure.

In an embodiment, the at least two plane inductors may include the first plane inductor and the second plane inductor, and the functional modules may include includes a chip and a package substrate. The first plane inductor may be formed in a metal layer of the chip, and the second plane inductor may be formed in a metal layer of the package substrate.

Exemplarily, as shown in FIG. 4, the at least two plane inductors include the first plane inductor 211 and the second plane inductor 212, and the functional modules include the chip 101 and the package substrate 102. The first plane inductor 211 is formed in the first metal layer 201 of the chip 101, and the second planar inductor 212 is formed in the second metal layer 201 of the package substrate 102. The chip may be a flip chip, and the connection part 30 may be a tin ball and/or a copper pillar for bonding the flip chip. As shown in FIG. 4, the connection part 30 is the tin ball. The tin ball for bonding the flip chip is used for forming the connection part 30 so that the thickness of the connection part 30 is greater than 50 μm. In this case, the distance between the first plane inductor 211 and the second plane inductor 212 can be sufficiently large to effectively increase the Q value of the inductor.

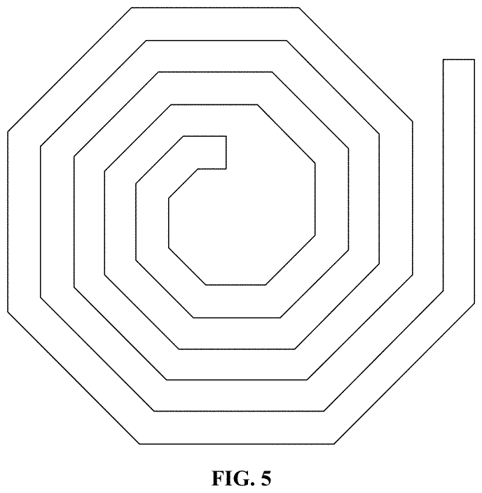

Based on the above technical solution, the embodiment of the present disclosure performs electromagnetic simulation on the integrated inductor structure of the present disclosure shown in FIGS. 2 and 3 and a single-layer plane inductor structure in the related art shown in FIG. 5 separately, and simulation results are shown in Table 1. Areas occupied by the integrated inductor structure and the single-layer plane inductor structure are same, and the integrated inductor structure and the single-layer plane inductor structure each have a length of 0.9 mm and a width of 0.9 mm. The thicknesses of the plane inductors in the integrated inductor structure and the single-layer plane inductor structure are both 20 μm, and the inductance values of the integrated inductor structure and the single-layer plane inductor structure are set to 4.3 nH. The thickness of the connection part in the present disclosure is 60 μm, and the first plane inductor and the second plane inductor are connected in series through the connection part.

TABLE 1
Inductance values and quality factors (Q value) of inductors in the
related art and this embodiment

| | Length | Width | Area | Inductance value | Q value |
|---|---|---|---|---|---|
| | (mm) | (mm) | (mm²) | (nH@1 GHz) | (@1 GHz) |
| Related art | 0.9 | 0.9 | 0.81 | 4.3 | 43 |
| This embodiment | 0.9 | 0.9 | 0.81 | 4.3 | 58 |

Note: the unit of the inductance value is nH, and in a case of a measurement frequency of 1 GHz, is expressed as nH@1 GHz. The Q value is dimensionless, and in a case of the measurement frequency of 1 GHz, is expressed as @1 GHz.

Referring to Table 1, compared with the inductor structure in the related art, in this embodiment, with the same inductor area and inductance value, the Q value of the inductor can be significantly improved.

In another aspect, an embodiment of the present disclosure provides an integrated circuit, including an integrated inductor structure provided by any embodiment of the present disclosure.

The integrated circuit provided by this embodiment includes the integrated inductor structure provided by the above embodiment, and has the same functions and beneficial effects, which is not repeated here.

1. An integrated inductor structure, comprising:
at least two plane inductors, which are sequentially stacked, wherein different ones of the at least two plane inductors are formed in metal layers of different functional modules; and
at least one connection part, which is disposed between adjacent ones of the functional modules, wherein each two adjacent ones of the at least two plane inductors are electrically connected through a respective one of the at least one connection part.

2. The integrated inductor structure of claim 1, wherein an electrical connection mode of the at least two plane inductors is at least one of: series connection and parallel connection.

3. The integrated inductor structure of claim 1, wherein the each two adjacent ones of the at least two plane inductors have an overlapping part in a direction perpendicular to a plane in which the at least two plane inductors are located.

4. The integrated inductor structure of claim 3, wherein the overlapping part of the each two adjacent ones of the at least two plane inductors has a same current direction.

5. The integrated inductor structure of claim 1, wherein each of the at least two plane inductors is a plane spiral structure.

6. The integrated inductor structure of claim 1, wherein the connection part comprises at least one of: a solder ball and a metal pillar.

7. The integrated inductor structure of claim 1, wherein the at least two plane inductors comprise a first plane inductor and a second plane inductor, and the functional modules comprise a chip and a package substrate; and
the first plane inductor is formed in a metal layer of the chip and the second plane inductor is formed in a metal layer of the package substrate.

8. The integrated inductor structure of claim 7, wherein the chip is a flip chip.

9. The integrated inductor structure of claim 8, wherein each of the at least one connection part is at least one of: a tin ball and a copper pillar for bonding the flip chip.

10. An integrated circuit, comprising an integrated inductor structure, wherein the integrated inductor structure comprises:
at least two plane inductors, which are sequentially stacked, wherein different ones of the at least two plane inductors are formed in metal layers of different functional modules; and
at least one connection part, which is disposed between adjacent ones of the functional modules, wherein each two adjacent ones of the at least two plane inductors are electrically connected through a respective one of the at least one connection part.
